(19) United States
(12) Patent Application Publication
(10) Pub. No.: US 2025/0246401 A1
(43) Pub. Date: Jul. 31, 2025

(54) Automatic Beam Uniformity Correction Through Generative AI Modeling

(71) Applicants: Niles Batchelder, Beverly, MA (US); Asad Anees, Beverly, MA (US); James Deluca, Beverly, MA (US)

(72) Inventors: Niles Batchelder, Beverly, MA (US); Asad Anees, Beverly, MA (US); James Deluca, Beverly, MA (US)

(21) Appl. No.: 19/009,104

(22) Filed: Jan. 3, 2025

Related U.S. Application Data
(60) Provisional application No. 63/625,030, filed on Jan. 25, 2024.

(51) Int. Cl. H01J 37/317

(52) U.S. Cl. CPC H01J 37/3171; H01J 2237/30427; H01J 2237/31701

(57) ABSTRACT

In one embodiment, the disclosure relates to using artificial intelligence (AI) to implement automatic beam current density distribution tuning by obtaining measurements from stationary beam current measurement devices synchronously with the motion of a scanned ion beam to predict the beam tuning settings which will produce a desired beam current density profile. An exemplary method according to the disclosed embodiments include the steps of generating an ion beam as a function of an ion source; scanning the spot ion beam; obtaining signals from a plurality of stationary sensors; synchronizing the beam current measurements with the scanning of the beam to produce an input waveform; predicting the beam tuning controls that will produce the desired beam current density profile; and applying the predicted settings to the beam control system and validating that the beam current density profile matches the desired profile within a specified limit.

The Instant Application claims priority to the Provisional Application No. 63/625,030 (filed Jan. 25, 2024) and entitled “Automatic Beam Uniformity Correction Through Generative AI modeling”, the disclosure of which is incorporated herein in its entirety.

### FIELD

The disclosure generally relates to method, system, and apparatus for automatic tuning of the ion beam current density distribution (i.e., beam profile) in the area of a workpiece by employing Generative artificial intelligence (AI). In one embodiment, the disclosure relates to using generative AI to implement automatic ion beam current density distribution tuning by obtaining measurements from stationary beam current measurement devices synchronously with the motion of the ion beam to generate the settings for the beam tuning controls which produce a desired beam current density profile in the region of the workpiece.

### BACKGROUND

In manufacturing semiconductor devices, ion implantation is used to selectively introduce impurities into (e.g., dope) a workpiece. The workpiece is typically provided in the form of a substrate such as a silicon, silicon carbide or gallium arsenide wafer. The wafer is bombarded with impurities or dopants to modify the electrical characteristics or otherwise transform material properties of the substrate. Ion implantation systems are well-known in the semiconductor manufacturing field, as capital equipment utilized to dope workpieces or to form passivation layers during fabrication of an integrated circuit by implanting ions from an ion beam into the workpiece. When used for doping semiconductor wafers, the ion implantation system injects a selected ion species into the workpiece to produce the desired extrinsic material.

Typical ion implantation systems include an ion source for generating electrically charged ions from ionizable source materials. The generated ions are formed into a beam and accelerated with the help of a strong electric field so as to be directed along a predetermined beam path to an implantation end station. Implanting ions generated from source materials such as antimony, arsenic, or phosphorus, for example, results in an n-type extrinsic material wafer, whereas a p-type extrinsic material wafer often results from ions generated with source materials such as boron, gallium, or indium.

The ion implantation system conventionally includes beam forming, steering, deflecting, shaping, filtering and charging subsystems (e.g., beam optical elements or beam optics) positioned between the ion source and the end station. The beam optical elements manipulate and maintain the ion beam along an elongated interior cavity or passageway (e.g., beamline) through which the ion beam passes on route to the end station where the workpiece is positioned.

The goal of the implantation process is to deliver a precisely controlled amount of dopant uniformly over the entire area of the surface of the workpiece or wafer. The most widely accepted approach for this process is embodied in a so-called serial implantation architecture, where individual workpieces are sequentially provided to an end station for implantation by the ion beam.

### SUMMARY OF THE DISCLOSURE

The disclosed embodiments relate to applying generative Artificial Intelligence (AI) to achieve more rapidly a desired flux density profile within the region of interest of a workpiece on an ion implantation system. In one embodiment, an ion source generates an ion beam. The ion beam is then transported through a beamline containing a plurality of subassemblies configured to tune the intensity, shape and position of the ion beam. In one embodiment, one of the subsystems is configured to scan or otherwise displace the ion beam in a direction orthogonal to the motion of a workpiece. In one embodiment, the scanned beam is then directed to a processing chamber having one or more stationary beam current measurement devices. The signals from one or more of the stationary beam current measurement devices are synchronized with the displacement of the ion beam and used as input signals to an AI module. The AI module in communication with a control system, is used to translate the input signals into a predicted adjustment or set of adjustments to one or more of the controls for one or more of the subassemblies which are configured to adjust the intensity, shape or position of the ion beam. These adjustments to the tuning of the beam can produce a desired beam current density profile in the region of the workpiece.

In one embodiment, the input signals may be signals from the stationary beam current measurement devices synchronized with the scanning of an ion beam and the predicted adjustments to the beam controls may be a waveform controlling the scanning of the ion beam. The stationary measurement devices may be Faradays or any other sensor which is sensitive to the ion beam current. Exemplary stationary measurement devices may include any number of Faradays placed in or near the region of the workpiece. Exemplary beam measurement devices may also include power supply current measurements connected to electrodes which may be exposed to positive or negative charges in the proximity of the ion beam making the power supply output current sensitive to the ion beam. The measured sampled signals from such devices may be used independently or in combination with each other. The input signals are then translated to a predicted set of beam tuning controls (which in this embodiment is a waveform to be applied at the subsystem or subassemblies configured to scan the ion beam) by the AI model. The control system then applies the predicted scanning waveform at the scanner to modify the beam current density profile in the region of the workpiece.

In another embodiment, a series of adjustments to beam tuning controls such as magnet currents, power supply voltages or motor positions is generated by measuring the input signals from one or more stationary beam current measurement devices as the ion beam is moved across them. The stationary measurement devices may be Faradays or any other sensor which is sensitive to the ion current density.

In some embodiments, a traveling Faraday may be used to measure a beam current density profile in a region of interest, typically in close proximity to the location where the workpiece will be implanted. The data from this measurement may be additionally used as an input signal to subsequent iterations of predictions by the generative AI model. The disclosed embodiments are generative, recipe independent and provide a significantly faster ion beam setup time than conventionally possible.

An embodiment of the disclosed principles relate to a computer system in communication with an ion implantation system, comprising: a memory circuitry comprising an executable code; a central processing unit (CPU), Graphical processing unit (GPU) and multi-core processors in communication with the memory circuitry and configured to execute the code, the executed code causing the ion implantation system to: generate an ion beam as a function of an ion source; scan the ion beam to form an elongated region of the scanned ion beam; obtain input signals from one or more stationary sensors; synchronize the signals from the stationary sensors with the motion of the ion beam to create an input waveform; apply an AI model to the input waveform to predict a set of beam tuning adjustments (such as a beam scanning waveform); and apply the adjustments to the subsystems controlling the intensity, shape or position of the ion beam to achieve a desired beam current density profile in a region of interest such as the location where the workpiece will be implanted.

relate to a non-transitory machine-readable medium with instructions stored thereon that when executed, the instructions cause a programmable device in communication with an ion implantation system to: generate an ion beam as a function of an ion source; scan the ion beam to form an elongated region of the scanned ion beam; obtain input signals from one or more stationary sensors; synchronize the signals from the stationary sensors with the motion of the ion beam to create an input waveform; apply an AI model to the input waveform to predict a set of beam tuning adjustments (such as a beam scanning waveform); and apply the adjustments to the subsystems controlling the intensity, shape or position of the ion beam to achieve a desired beam current density profile in a region of interest such as the location where the workpiece will be implanted.

In still another embodiment, the disclosure provides a method to generate and apply target adjustments to control ion implantation as a workpiece is processed, the method comprising: generate an ion beam as a function of an ion source; scan the ion beam to form an elongated region of the scanned ion beam; obtain input signals from one or more stationary sensors; synchronize the signals from the stationary sensors with the motion of the ion beam to create an input waveform; apply an AI model to the input waveform to predict a set of beam tuning adjustments (such as a beam scanning waveform); and apply the adjustments to the subsystems controlling the intensity, shape or position of the ion beam to achieve a desired beam current density profile in a region of interest such as the location where the workpiece will be implanted.

### BRIEF DESCRIPTION OF THE DRAWINGS

Certain disclosed embodiments will now be described with reference to an exemplary ion implantation system as depicted in the accompanying figures, in which like reference numerals may be used to refer to like elements throughout. It should be understood that the description of these aspects is merely illustrative and nonlimiting. In the following description, for purposes of explanation, numerous specific details are set forth in order to provide a thorough understanding of the present invention. It will be evident to one skilled in the art, however, that the present invention may be practiced without some of these specific details. The drawings include:

FIG. 1 is a representative system architecture of an ion implantation system according to certain disclosed embodiments;

FIG. 2A illustrates an exemplary electrostatic scanner and an exemplary scanning process;

FIG. 2B illustrates an exemplary waveform generated by the scanner of FIG. 2A;

FIG. 2C is a waveform diagram resulting from the application of time varying magnetic field of the electrostatic poles shown in FIG. 2A;

FIG. 2D illustrates scanned and parallelized beam impacting a workpiece at the corresponding times indicated in FIGS. 2B-2C;

FIG. 3 is an exemplary flow-diagram for implementing an embodiment of the disclosure;

FIG. 4 illustrates an exemplary initial scanning waveform which produces a time varying magnetic field for displacement of an ion beam;

FIG. 5 is a schematic representation of an exemplary process chamber according to one embodiment of the disclosure containing multiple devices which are sensitive to beam current;

FIG. 6 shows several exemplary target waveforms (or target adjustments) obtained using the generative AI model in one of the disclosed embodiments;

FIG. 7 is a schematic representation of an exemplary AI training process according to one embodiment of the disclosure;

FIG. 8 schematically illustrates an application of certain disclosed principles to obtain a set of adjustments to the ion beam tuning from the stationary sensor signals in which the set of adjustments defines a waveform to be applied to a beam scanning system;

FIG. 9 schematically shows an exemplary embodiment of the disclosure in which an AI generated target waveform is applied to a beam scanner;

FIG. 10 schematically illustrates a process flow diagram for continuously collecting data and updating the AI generative model;

FIG. 11 schematically illustrates an exemplary system for implementing an embodiment according to the disclosed principles; and

FIG. 12 schematically illustrates a simplified synchronization architecture according to one embodiment of the disclosure.

### DETAILED DESCRIPTION

In the following description, for purposes of explanation, numerous specific details are set forth in order to provide a thorough understanding of the invention. It will be apparent, however, to one skilled in the art that the invention may be practiced without these specific details. In other instances, structure and devices are shown in block diagram form in order to avoid obscuring the invention. References to numbers without subscripts or suffixes are understood to reference all instances of subscripts and suffixes corresponding to the referenced number. Moreover, the language used in this disclosure has been selected principally for readability and instructional purposes and may not have been selected to delineate or circumscribe the inventive subject matter, resort to the claims being necessary to determine such inventive subject matter. Reference in the specification to “one embodiment” or to “an embodiment” means that a particular feature, structure, or characteristic described in connection with the embodiments is included in at least one embodiment of the invention, and multiple references to “one embodiment” or “an embodiment” should not be understood as necessarily all referring to the same embodiment.

The embodiments described herein are examples and for illustrative purposes. Persons of ordinary skill in the art will recognize that alternative techniques for implementing the disclosed subject matter may be used. Elements of example embodiments may be arranged in different arrangements or combined with elements of different example embodiments. For example, the order of execution of blocks and flow charts may be changed. Some of the blocks of those flowcharts may be changed, eliminated, or combined and other blocks may be added as desired.

As used herein, the term “a computer system” can refer to a single computer or a plurality of computers working together to perform the function described as being performed on or by a computer system.

To maintain a desired implantation dopant profile, the ion beam current is often measured during implantation. One or more measurement devices, typically Faradays, are placed along the path of the ion beam, typically in front of, adjacent to, or behind the processing area of the workpiece. In one embodiment, one or more Faradays are placed horizontally adjacent to the area where the workpiece is processed, and the ion beam is scanned across the workpiece and these Faradays. A tuning Faraday or Faradays may also be positioned upstream or downstream of the typical location of the workpiece for tuning of the ion beam when the workpiece is not present or is in a position such that at least a portion of the ion beam does not impinge on the workpiece. In addition, a traveling (interchangeably, profiling) Faraday cup can be used to monitor the ion beam as this Faraday is translated through the region where the workpiece will be implanted. The traveling Faraday may be a single collector which measures the entire beam or may be segmented to provide information about the ion beam current density in the direction orthogonal to the faraday direction of travel. The traveling Faraday is typically used to measure the flux density profile in the region of the workpiece for the purpose of confirmation that the observed flux profile matches the desired flux profile within a specified limit. Other devices such as power supply readbacks may also measure the beam flux directly or indirectly. All (or some) of such sampling cups or other measurement devices may be used to monitor the current of the ion beam entering the end station. The measured current of the ion beam may be used to adjust implant compensations to control local exposure times of the workpiece to the ion beam to provide the desired dosing profile across the workpiece surface.

For repeatable doping of workpieces in the ion implantation processes it is critical to achieve and maintain a desired beam flux profile within a specified limit. On scanned spot beam systems nonuniformities can be compensated by modulating the waveform that describes the velocity (or interchangeably, dwell time) of the ion beam at specific locations on the workpiece. The ion beam dwells longer where the derivative in the waveform is low which increases the local flux and therefore implanted dose. Conversely, the ion beam dwells shorter where the derivative in the waveform is higher lowering the local flux and therefore implanted dose. Beam setup, tuning, and profiling steps are time consuming and reduce the operational efficiency of the machine. Uniformity corrections are a significant portion of each new process setup time and have historically required a minimum of two physical motions of a traveling Faraday to complete. Typically, the first measurement of the flux density profile in the region of the workpiece uses a pre-defined ion beam scanning waveform such as a pure triangle wave where the derivatives are constant except where the beam scanning changes direction. In some embodiments, this motion and subsequent data processing and calculation can take as much as 20 seconds. The data calculation takes the beam flux information from the traveling Faraday and determines local changes to the derivatives within the waveform intended to match the observed beam current density profile to a desired flux profile. A second scanned beam flux profile is made with the newly calculated waveform which may take an additional 20 seconds or more. Further iterations of the waveform adjustment and the scanned beam flux profiles may occur until the desired flux profile and any other specified limits are achieved. This iterative process can lead to machine inefficiency.

In conventional techniques, a traveling beam current measurement device, often a faraday, is slowly moved through the workpiece implantation area and the ion beam current density is measured at each location within this area. This flux density profile may be used as an input to calculate adjustments to beam tuning knobs such as an oscillatory scanning voltage or current such that the flux density profile is adjusted to match a desired profile within a specified level.

The flux density of the scanned ion beam in the region of the workpiece may differ in unpredictable ways from beam setup-to-setup even for nominally identical input tuning parameters. These changes can be manifestations of long-term wear of beamline components, drift in voltage or current controlled power supplies or eddy currents or hysteresis in electromagnets. These variations can also be manifestations of short-term fluctuations or spikes in current distribution (i.e., beam profile) caused by disparities in beam shape and/or angle, shifting of current distribution within the ion beam, system noise, or particle contamination along the ion beamline, among other factors. Other factors can include changes in the beamline pressure, emission from elements exposed to the beam, and beam interaction with the workpiece as it is moved through the beam. The semiconductor device manufacturing process allows for some tolerance in the doping uniformity of the workpiece. However, the sensitivity of each process to dose will dictate how closely the actual doping level must match a desired profile.

A conventional technique to address this requirement is known as point-to-point corrections in which a traveling profiler traverses through a region of interest to measure the beam flux at each location. The waveform supplied to the scanning system is then adjusted in piecemeal and without prior knowledge of the implanted dopant. Thus, if the measured flux were relatively high at a first location, the waveform would be adjusted so the beam scans faster on that location to reduce the relative flux as a corrective measure,

Another conventional technique uses high speed data collection from a traveling profiler as it moved through the implantation region synchronized with the signal controlling the scanning of the ion beam. This creates a series of pseudo-stationary beam profiles indexed to each of the commands provided to the scanning system. The summation of the current from each of these pseudo-stationary profiles at each position of the traveling profiler provides the flux at that location. The full array of these beam current density measurements indexed to profiler location is the flux density profile within the area of the workpiece. The change to beam current density profile by adjusting the dwell time at each of the commands at the scanner can be calculated by applying a weighting factor to each profile. A “dynamic marker” (e.g., as described in U.S. Pat. No. 8,421,039) regression algorithm rapidly finds the relative dwells necessary to minimize the residuals to the average flux density across the area of the workpiece to a target flux density profile and converts these desired dwells into a waveform to provide to the scanning system. While expediting correction, this method depends on data collected by the traveling Faraday which is moved through the region of interest while the beam is scanned using a default starting scan waveform (typically a purely or close to purely triangular waveform). With the default starting waveform is typically unlikely to match the desired flux density profiler therefore requiring an iterative process through the measure, correct, measure loop. This technique is time consuming as it requires a significant setup and travel time for the traveling profiler.

The subsequent iteration of technology relied on predictive methods in which prior recipes (last known waveform) were applied as the starting waveform. Such techniques were corrective only when prior measurements were available and if these measurements and the instrument were identically tuned and the environment of the beamline (such as aging of beamline components or residual gas density) remained identical. Due to the necessity of the identical recreation of beamline environment this prior recipe waveform solution often fails to provide a complete solution resulting in the requirement for iterative correction attempts resulting in efficiency loss.

The disclosed embodiments address these and other shortcomings of the art by providing a generative solution. The generative solution may be implemented by AI and a neural network trained to detect and correct differences between the actual and desired beam current density profile. The disclosed embodiments do not require a traveling Faraday nor known recipes for generating the initial set of beam tuning adjustments which shall have a high probability of meeting the desired beam current density profile upon the first measurement thereof. In certain embodiments, the disclosure provides a system, method and apparatus to use time-varying or space-varying signals from one or more stationary beam current measurement devices to generate a predicted set of adjustments to the tuning of the ion beam which provides a higher probability of matching the desired beam current density profile the first time it is measured by a traveling beam current measurement device. The disclosed embodiments are generative in that corrective data is obtained in real-time from stationary measurement device without reliance on recipe-specific data. The disclosed embodiments adapt quickly to system changes and to new recipe conditions. The disclosed embodiments continuously improve the tool efficiency and beam current density profile corrections as the generative model can respond immediately to environmental drift which may change the shape of the ion beam and thus the tuning adjustments required to match the desired current density profile within a specified limit.

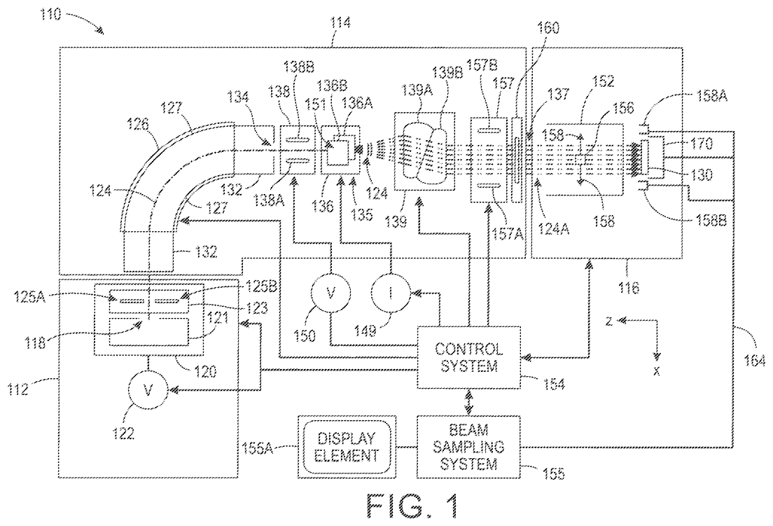

FIG. 1 is a representative system architecture of an ion implantation system according to certain disclosed embodiments. Specifically, FIG. 1 illustrates an exemplary ion implantation system 110 wherein an ion beam and/or system can be controlled as described herein. While the exemplary system shown in FIG. 1, represents a so-called hybrid or scanned spot beam ion implantation system architecture, it will be understood that the disclosed principles will be applicable regardless of the size of the ion beam or the degree to which the ion beam is displaced across the stationary measurement devices such that a similar generative algorithm may be applicable to the case of large beams with small displacement to predict the appropriate tuning knobs necessary to adjust the current density profile of the ion beam itself to meet the desired density profile within a specified limit.

System 110 includes terminal 112, beamline assembly 114, and end station 116. Terminal 112 includes ion source 120 powered by a high voltage power supply 122 that produces and delivers ion beam 124 to beamline assembly 114. Ion source 120 generates charged ions that are extracted and formed into ion beam 124. Ion Beam 124 is directed along a beam path in beamline assembly 114 to end station 116. Terminal 112 may be described as comprising some of the beamline, where that portion of the beamline is at terminal potential.

To generate the ions, precursor material (not shown) to be ionized is provided within generation chamber 121 of ion source 120. The dopant material can be introduced directly in the form of a precursor gas which can, for example, be fed into chamber 121 from a gas, liquid or vaporized solid source (not shown) or may be formed by sputtering a target in chamber 121 using non-dopant ions generated from another, typically inert, input gas. In addition to power supply 122, it will be appreciated that any number of suitable mechanisms (none of which are shown) may be used to excite free electrons within ion generation chamber 121, such as: RF or microwave excitation sources; electron beam injection sources; electromagnetic sources; and/or a cathode which creates an are discharge within the chamber, to name a few. The excited electrons collide with the precursor gas molecules to generate ions. Generally, positive ions are selected for implantation although the disclosure herein is equally applicable to systems wherein negative ions are generated.

Ions generated in chamber 121 are controllably extracted therefrom through an aperture or arc slit 118 by means of ion extraction assembly 123. Ion extraction assembly 123 may comprise a plurality of extraction and/or suppression electrodes, comprising symmetric electrode pairs 125A and 125B situated on opposite sides of arc slit 118. The electron pair extracts ions in the form of a dense ray of ions or an ion beam 124. Extraction assembly 123 may include, for example, a separate extraction power supply (not shown) for biasing the extraction and/or suppression electrodes 125A and 125B to induce extraction of ions from generation chamber 121 in the form of the ion beam 124 and to accelerate ion beam 124 downstream in the direction of beamline assembly 114.

Since ion beam 124 comprises like charged particles, the beam may have the tendency to expand or blow-up radially outwardly as the like charged particles within the beam tend to repel one another. Beam blow up can be exacerbated in low energy, high current (high perveance) beams where many like charged particles are moving in the same direction, and relatively slowly, such that there is an abundance of repulsive forces among the like charged particles, but little particle momentum to keep the particles moving in the direction of the beam path. Accordingly, extraction assembly 123 is generally configured such that the beam is extracted at a high energy so that the beam does not blow up (i.e., so that the particles have sufficient momentum to overcome repulsive forces that can lead to beam blow up). While low energy drift applications are known and could make use of the disclosed principles, it is advantageous to transport ion beam 124 at a relatively high energy throughout the system, wherein the energy of the ion beam is reduced immediately prior to impacting workpiece 130. This method of transporting the beam at high energy and then decelerating the beam close to the implantation target reduces the path length over which the beam may blow-up thus improving beam transport. In certain embodiments, molecular or cluster ions are generated and transported at a relatively high energy but are implanted with a lower equivalent energy, since the energy of the molecule or cluster is divided amongst the implanted atoms of the molecule.

Referring again to FIG. 1, beamline assembly 114 generally includes mass analyzer unit 126 and beam-guide 132 defining resolving aperture 134 at an exit of beam-guide 132. The beamline assembly includes various beam focusing and/or steering components 138, scanning system 135, parallelizer 139, and angular energy filter 157, (individually, beam optical elements or collectively, beam optics). The beam optics may include a charge neutralization subsystem 160 for providing a source of negatively charged particles such as electrons to the beamline and/or workpiece to be implanted to counteract beam blow up and other potential charging problems by matching the ion beam current with an electron current sufficient to neutralize the beam charge. Collectively, these various beamline components are referred to herein as beam optics or beam optical elements.

Mass analyzer 126 comprises one or more magnets that serve to establish a dipole magnetic field. As beam 124 enters mass analyzer 126, it is correspondingly bent by the magnetic field such that ions of an inappropriate mass-to-charge ratio are rejected from the ion beam. More particularly, ions having too great or too small a mass-to-charge ratio are deflected into side walls 127 of mass analyzer 126, while ions in having the desired mass-to-charge ratio are allowed to pass therethrough and exit through a resolving aperture 134.

Scanning system 135 in the illustrated example may include an electrostatic or a magnetic scanning element 136 and optional focusing and/or steering element 138. Respective power supplies 149, 150 are operatively coupled to scanning element 136 and focusing and steering element 138, and more particularly to respective electrodes 136A, 136B and 138A, 138B, Focusing and steering element 138 receives mass analyzed ion beam 124 having a relatively narrow profile (e.g., a so-called spot or pencil beam), and a voltage applied by power supply 150 to the plates 138A and 138B operates to focus and steer the beam, to a desired scan point such as a scan vertex 151 of scanning element 136. A continuously variable current waveform provided by power supply 149 to scanner plates 136A and 136B causes ion beam 124 to be deflected and scanned back and forth, producing an elongated, ribbon-shaped, ion beam (e.g., a scanned spot beam). In certain embodiments, the scanned beam defines a width that is at least as wide as, or wider than, workpiece 130 being implanted by the scanned beam.

It will be appreciated that focusing and/or steering element 138 may be made up of one or a plurality of elements and/or subsystems and are commonly provided in the form of a quadrupole magnet commonly used in ion focusing. Various alternative elements such as, for example, an Einzel lens or other unipontential or multipotential lens structure can be incorporated to provide ion beam optics for focusing or deflecting ions in flight, which is accomplished through manipulation of the electric or magnetic fields in the path of the ions by varying the voltages applied to the electrodes of the various beam optical elements,

Once scanned beam 124 is passed through scanning system 136, the beam is then passed through parallelizer 139, which, in the illustrated embodiment, comprises two dipole magnets 139A, 139B. The dipoles may have equal angles and opposite bend directions such that the dipoles are substantially trapezoidal and are oriented to mirror one another to cause beam 124 to bend along a substantially an S-shaped path. The primary purpose of the dipoles is to cause the divergent beamlets originating from scanner 136 to become parallel, thereby forming a ribbon shaped beam having substantially parallel beamlets. The use of two symmetric dipoles results in symmetrical properties across the ribbon beam in terms of beamlet path length and first and higher order focusing properties. Parallelizer 139 causes scanned beam 124 to alter its path such that beam 124 travels parallel to a beam axis regardless of the scan angle at which a particular beamlet exits the scanner so that the implantation angle at which the beamlet strikes workpiece 130 is relatively uniform across the surface thereof.

Although deceleration of scanned beam 124 is not required, one or more deceleration stages 157 are located downstream of parallelization component 139 in FIG. 1. In system 110, beam 124 is generally transported at a relatively high energy level for mitigating against the propensity for beam blow up, which can be particularly high where beam density is elevated such as at resolving aperture 134. Deceleration stage 157 comprises one or more electrodes 157A, 157B operable to decelerate beam 124. Electrodes 157 are typically apertures through which the beam travels and may be drawn as straight lines in FIG. 1. Although a pair of electrodes are shown and described as the components making up deceleration stage 157, as well as any of the components making up the beam optics of system 110 may comprise any suitable number of electrodes arranged and biased to accelerate and/or decelerate ions, as well as to focus, bend, deflect, converge, diverge, scan, parallelize and/or decontaminate ion beam 124.

The ion beamline can also include a charge neutralization subsystem such as plasma electron flood device 160, which produces neutralizing electrons in a region through which the ion beam passes for counteracting charge imbalance within the ion beam. Thus, charges within the ion beam can be compensated for by providing electric charge having a polarity opposite to the ion beam. For example, in the case of a positively charged ion beam, it is common practice to make available electrons in an amount equal or greater quantity as the ions provided to the workpiece, thereby allowing the ion beam to conduct electron current to the workpiece as required to maintain neutral surface potential. This is typically brought about by a device that produces electrons via electron generating processes such as thermionic emission, secondary emission, discharge, microwave or RF field, wherein the low energy electrons form a cloud through which the beam travels prior to implantation into a workpiece. These devices are typically designated electron guns, secondary electron flood, plasma electron flood, etc.

End station 116 provides a processing chamber for receiving ion beam 124 and leading the beam toward workpiece 130. It will be appreciated that different types of end stations 116 may be employed in implanter 110. End station 116 in the illustrated example is a serial-type end station, which supports a single workpiece 130 along the beam path for implantation. A serial-type end station supports a single workpiece 130 along the beam path for implantation and multiple workpieces 130 are implanted one at a time in serial fashion. Each workpiece 130 being completely implanted before implantation of the next workpiece 130 begins. In the case of a scanned beam serial type system, workpiece 130 is mechanically translated in a first (Y or slow scan) direction while the beam is scanned to and fro in a second (X or fast scan) direction in order to impart beam 124 over the entire workpiece 130.

Before and during ion implantation of workpiece 130, it is desirable to monitor the ion beam to determine various characteristics and parameters thereof, including beam current, beam current density, beam current distribution (profile) and a general dosage of ions expected to be implanted into the workpiece for process control and other reasons. In addition, parameters such as beam angle (e.g., horizontal beam angle, vertical beam angle) and divergences (in both horizontal and vertical directions), as well as size (beam width and height) can be monitored. Beam sampling system 155 and other associated hardware components are integrated into end station 116 for monitoring and sampling the ion beam at a predetermined frequency (e.g. 1 Hz, 20 Hz, 250 KHz, or any other frequency). This provides a plurality of discrete beam current sample measurements for analysis.

In an exemplary system, one or more stationary beam current measurement devices 158A, 158B (interchangeably, sampling cups or dose cup) are provided generally adjacent to wafer 130 along the axis of the scanned ion beam 124, wherein one or more properties (e.g., a beam current) of the ion beam are sampled and measured as the ion beam is scanned and passes over the one or more side Faraday cups. For example, beam sampling system 155 receives signal 164 comprising a plurality of sequential beam samples from the one or more side Faraday cups 158A, 158B and outputs the measured samples of the one or more properties of ion beam 124 to control system 154. The sampled output may define the input signal. The collection of these samples is synchronized with scan voltage or current waveform provided to scanner 136, as well as to the position of scanned workpiece (endpiece) 130 to provide time and position dependent beam current information to the control system. The control system may use the input signal and such additional information to generate a set of target adjustments for the ion implantation system 110. The target adjustments may be adjustments to magnet currents, power supply voltages or define a target waveform which controls the speed and movement of scanner 136.

In the example of FIG. 1, one or more side beam current measurement devices 158A, 158B are generally positioned adjacent to and outboard of workpiece 130 (e.g., outside the circumference of the workpiece), along the path of scanned ion beam 124 as it is scanned across workpiece 130. The scanned beam preferably has a width (the scan width) that extends beyond the dimension of the workpiece and is shaped to pass the scanned ion beam 124 far enough to collect a signal in one or more of the side mounted beam current measurement devices 158A, 158B positioned outside the circumference of the workpiece.

In addition, tuning (or tune) beam current measurement device 170 is provided downstream of and behind workpiece 130, where beam sampling system 155 further receives high frequency samples from this measurement device 170 and generally outputs the measurement of the one or more properties of ion beam 124 to the control system 154. The measurement device 170 is conventionally used when the workpiece 130 is either not present (before an ion implantation cycle), entirely outside of the beam path (at either end of the mechanical scan sequence) or positioned partially outside of the beam scan path. The latter may occur when the workpiece is scanned to a position where the ion beam or a portion thereof can reach the measurement device 170 positioned downstream from the workpiece 130. The sampled beam measurement is generally synchronized to the scan voltage or current waveform provided to scanner 136, as well as to the position of scanned workpiece 130 to provide a time and position dependent beam current profile of the ion beam (i.e., input signal). Beam sampling system 155 may optionally include a presentation screen or graphic user interface 155A to display the time and position dependent beam current waveform of the scanned ion beam and the scan current waveform and other information of relevance to the system operator.

In addition to side mounted measurement devices 158A, 158B, and tuning measurement device 170, the beam sampling system may generally include input from one or more traveling measurement devices 156 (also referred to generically as a profiler). The traveling profiler 156 may comprise a current measurement sensor, such as a Faraday cup, which measures the current density of the scanned beam as the profiler moves. The current density sensor of traveling profiler 156 moves in a generally orthogonal fashion relative to the mechanical scan direction of the workpiece and thus typically traverses the width of the ion beam which may be a wide stationary beam or a spot beam which is scanned into a ribbon-like profile. This traveling profiler 156 may contain more than one current collector stacked orthogonally to the direction of travel of the profiler to simultaneously collect a two-dimension profile of the current density in the region of the workpiece. The profiler signals are typically generated before or after an implant cycle, wherein profiler 156 is transported through the ion beam to provide data and feedback to the ion implantation system during and/or after an ion implant cycle. Similar to the side mounted measurement devices 158A, 158B, and tuning measurement device 170, the monitored and sampled beam current measurements provided by the traveling profiler(s) can be generally correlated to the scan current or voltage waveform provided to the scanner 136, as well as the position of the travelling profiler to provide a time and position dependent beam current profile of the ion beam.

Control system 154 is coupled to the beam sampling system 155 for providing communication, control, and/or adjustment the various components and subsystems of ion implantation system 110, including: ion source 120 and electrodes 125 associated therewith; mass analyzer 127; beam steering and focusing system 138; scanning element 136; parallelizer 139; energy filter 157; and charge neutralizer system 160, (i.e., collectively, any one or more of the beam optical elements).

Control system 154 may comprise a computer, microprocessor, graphic processing units, multi-core processors, etc., and may be operable to store measurement values of beam characteristics (e.g., the beam current or density) and adjust parameters (e.g., bias voltages, gas pressures, magnet currents) applied to any one of the beam optical elements. Any of the beam optical elements may be adjusted by control system 154 to facilitate desired ion beam properties. For example, the strength and field generated in mass analyzer 126 can be adjusted, such as by regulating the amount of electrical current running through field windings therein to alter the curvature of the path of the desired ion beam. In addition, the angle of implantation can be further controlled by adjusting the voltage applied to steering element 138 as the current density delivered to wafer 130 can be a function of implantation angle (e.g., the relative orientation between the beam and the mechanical surface of the workpiece and/or the relative orientation between the beam and the crystalline lattice structure of the workpiece). The instantaneous voltages applied to any one of the beam optical elements may also be varied extemporaneously in response to beam current fluctuations detected by beam sampling system 155,

In an exemplary embodiment, beam sampling system 155 and control system 154 comprise one or more algorithm according to the disclosed principles to apply a generative AI model which may include reinforcement learning to provide automatic beam flux density tuning. In another embodiment, beam sampling system 155 and control system 154 cooperate to provide in situ beam current sampling by which the beam current and/or beam current density is monitored and to further provide control of the ion implantation system. In still another exemplary embodiment, beam sampling system 155 and control system 154 can cooperate to create a control signal for interlocking, aborting or halting ion beam transport in the event that a significant beam current non uniformity event occurs. In another embodiment, beam sampling system 155 and the control system 154 can cooperate to create a control signal for adjusting power supply outputs to selectively vary voltages and currents applied to the various beamline components and beam optical elements of the ion implantation system, through iterative or incremental means.

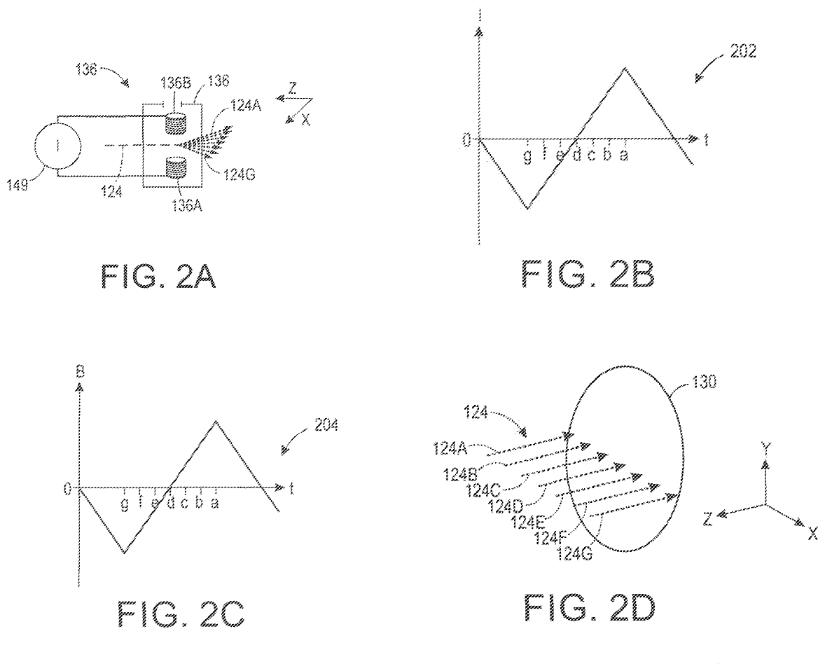

FIG. 2A illustrates an exemplary magnetic scanner. While all other scanning processes are contemplated within the disclosed principles, for simplicity the examples provided herein relate to a magnetic process. Scanner 136 of FIG. 2A receives mass analyzed ion beam 124 having a relatively narrow profile (e.g., a spot or a pencil beam). Scanner 136 comprises first magnetic pole 136A and second magnetic pole 136B situated on either vertical side of beam 124. The poles are separated by a gap comprising a vacuum through which the beam path 124 passes. Magnetic poles, 136A and 136B, may comprise conductive coils. A waveform operates to vary the current through coils 136A, 136B causing beam 124 to scan back and forth in the X direction (the scan direction), creating an elongated ribbon-type beam (e.g., a scanned spot beam), having an effective X direction width that has a region at least as wide as the workpiece over which the beam current density profile may be controlled to match a desired profile.

Referring to FIGS. 1 and 2A, scanned beam 124 is directed to the end station 116 (FIG. 1) such that the beam 124A strikes the workpiece for implantation. The scanned beam also strikes the measurement devices (e.g., Faraday cups, FIG. 1) coupled to the beam sampling system 155. Magnetic poles 136A and 136B are coupled to a current source 149, configured to provide alternating currents to the magnetic poles 136A and 136B, as illustrated.

FIG. 2B illustrates an exemplary waveform provided to the scanner of FIG. 2A. Waveform diagram 202 in FIG. 2B illustrates the result of applying a time-varying current to the magnetic poles. The time varying current between the magnetic poles forms a time varying magnetic field 204, as illustrated in a waveform diagram in FIG. 2C, extending outward from the coils across the beam path, by which beam 124 is bent or deflected (e.g., scanned) along a scan direction (e.g., the X-direction in FIG. 2A). When the scanner magnetic field is in the direction from pole 136A to pole 136B, (as indicated by times g-e in FIG. 2C), ions of beam 124 are subjected to a lateral force in the positive X direction. This causes beam spreading in the X direction. When poles 136A and 136B are subjected to zero current there is zero magnetic field in scanner 136 (such as at time d in FIG. 2C) and beam 124 passes through the scanner 136 unmodified. When the field is in the direction from pole 136B to pole 136A (i.e., times a-c in FIG. 2C), ions of beam 124 are subjected to a lateral force in the negative X direction. This causes beam 124 to spread in the −X direction.

FIG. 2D illustrates scanned and parallelized beam 124 impacting workpiece 130 at the corresponding times indicated in FIGS. 2B-2C. When the current through the poles is at a maximum and minimum (e.g., a negative maximum) the corresponding magnetic field strength will be at a maximum and minimum (e.g., a negative maximum) so that the beam can be found at the extremes of the beam scan path (e.g., at the far right and the far left edges beyond the workpiece 130), Discrete points of scanned beam 124A-124G are illustrated in FIG. 2D for scan currents at corresponding times a-g of FIG. 2B for a single generally horizontal scan in the X direction across workpiece 130. It follows that when the scanner magnetic field is in the direction from pole 136B to pole 136A, ions of the beam 124 are subjected to a lateral force in the negative X direction such that the scanned beam reverses the direction of the discrete points of the scanned beam 124G-124A illustrated in FIG. 2D to produce a single generally horizontal scan across the workpiece 130 in the negative X direction.

As stated, an embodiment of the disclosure relates to beam current distribution profile tuning through generative AI modeling, reinforcement learning and neural networks. In an exemplary method, stationary beam current measurement devices collect time-dependent data in the form of input signals. The collected signals, which represent characteristics of the beam as it moves through the region of the workpiece, are used to generate subsequent target adjustments to the tunning of the beam (e.g., the waveform provided to the beam scanning system) which are used to control the beam current density profile. While certain conventional techniques rely exclusively on existing recipes, the disclosed embodiments use real time data to generate the predicted beam tuning adjustments. In one embodiment of the disclosure, a combination of existing recipes (which may be saved on the tool), and generative methods are used to generate the predicted adjustments. By way of example, the disclosed generative methods may be used for the first-time setup and/or to implement changes to existing recipes to thereby maintain the desired beam current density profile. Because the disclosed embodiments rely on real time data collection, drift in the beam current, shape or position and other anomalies can be detected and immediately compensated for. The disclosed methods may be implemented in hardware, software or a combination of hardware and software. In one embodiment, a generative algorithm is stored on the tool (e.g., implantation equipment) and comprises one or more control circuitries and memory circuitries to direct the implantation equipment to generate corrective adjustments to the beam tuning (e.g. modification to the waveform used in beam scanning). These and other exemplary implementations are discussed below.

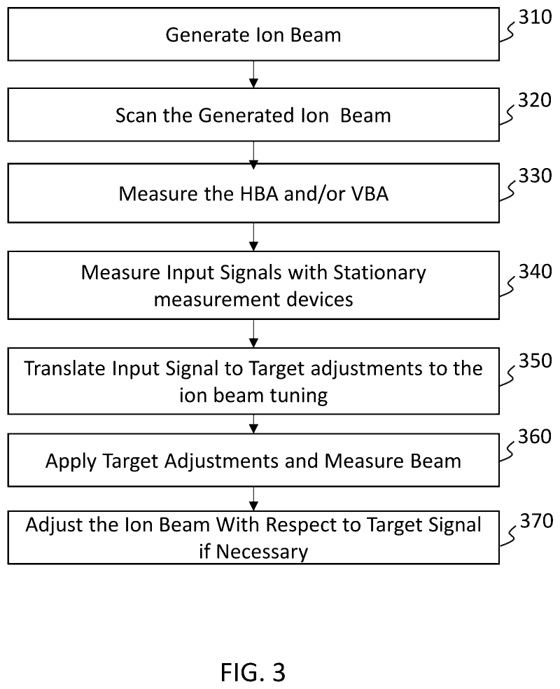

FIG. 3 is an exemplary flow-diagram for implementing an embodiment of the disclosure. The flow-diagram of FIG. 3 is described in relation to ion implantation 100 of FIG. 1. With reference to FIG. 3 and as used herein, the “input signal” is a readback of the beam (i.e., scanning-synchronized beam current measurements) and the “initial target waveform” is a (virtual) tuning knob controlling the beam. The “target” scanned waveform is a time varying signal that controls how long the spot beam dwells at various locations across the area of the workpiece. Thus, the input signals are time varying measurements (waveforms) of beam current versus time as the beam scans across the beam current measurement devices (i.e., faradays) for use in predicting the current density uniformity in the area of the workpiece and the adjustments to the scanning waveform necessary to change that uniformity profile to meet the desired profile. Put differently, a target is any predicted adjustments to the beam tuning (for example, tuning a DC magnet current or DC voltage or alternatively adjusting an AC scanner waveform magnetically or electrostatically that the AI model suggests should change the beam current density (uniformity) profile to meet the recipe limits.

At operation 310, the flow-diagram of FIG. 3 starts with generating ion beam 310. The ion beam may be generated at terminal 112 as discussed in relation to FIG. 1. At operation 320, the ion beam is scanned using a beam scanner, for example, scanner 136 of FIG. 1.

At operation 330 the horizontal and/or vertical beam angle (HBA and VBA) are measured. These measurements may be implemented during the autotune process. In one implementation, the angle is measured by placing one or more apertures in front of the scanned beam with a single traveling beam current measurement device. In another embodiment one or more masked beam current measurement devices may be used. The information about the ion beam angle, parallelism and angle distribution derived from these measurements may be provided as an input signal to the generative, reinforcement or neural network models for use in predicting the appropriate beam running adjustments for achieving the desired beam current density profile.

At operation 340, the stationary beam current measurement devices are used to collect a set of input signals according to certain disclosed principles. In one implementation, the input signal may be obtained by sampling a measurable attribute of the scanned beam (i.e., ion implantation beam) received at one or more stationary beam current measurement devices. The measurable attribute may be current of the scanned beam at the stationary measurement device. The observed input signal is sensitive to the initial tuning setup (e.g., the initial scanning waveform) and it is understood that different beam tuning such as different scanner waveforms will produce different input signals measured by the stationary beam current measurement devices.

The sensors may comprise one or more stationary beam current measurement devices (such as Faradays or electrodes which are connected to power supplies whose current output will depend on the quantity of charge striking such an electrode). In one embodiment, the beam current measurement devices (e.g., side “dose” Faradays 158A, 158B and center “tuning” Faraday 170) are used to obtain input signals for the AI model to thereby define the target beam tuning adjustments. In other embodiments, the input signals for the AI model may be obtained from: the side mounted beam current measurement devices alone (158A, 158B) or in combination, the central beam current measurement device (170) alone, the combination of the side mounted beam current measurement devices (158A, 158B) and the central beam current measurement device (170) or any other stationary measuring device. The signals collected from each beam current measurement device may be synchronized with the waveform controlling the motion of the ion beam. The measurement devices and the system controlling the motion of the ion beam may be implemented anywhere in ion implementation system 110.

At operation 350, the input signals from the stationary measurement devices are translated to a set of adjustments to the ion beam control knobs. In one embodiment, the input signals are translated using generative techniques disclosed herein to predict a waveform to be applied to the beam scanning system. The ion implantation system will implement the predicted changes to the beam control knobs (e.g., the waveform applied to the scanning system) to improve the implantation characteristics such as the beam current density profile in the area of the workpiece. In one embodiment, at operation 360, the target waveform predicted by the AI model of operation 350 is applied at the ion beam scanner and a new set of input signals is collected from the stationary beam measurement devices while the ion beam scans across the region of the workpiece. Finally, at operation 370, the beam current density in the region of the workpiece is confirmed. If the beam current density profile fails to match the desired profile within a specified limit the adjustment process may be repeated and once the specified limits are reached the process will be completed and the implantation system may proceed to either addition process setup steps or onto the processing of workpieces. The process of FIG. 3 may be repeated throughout the setup and implantation process.

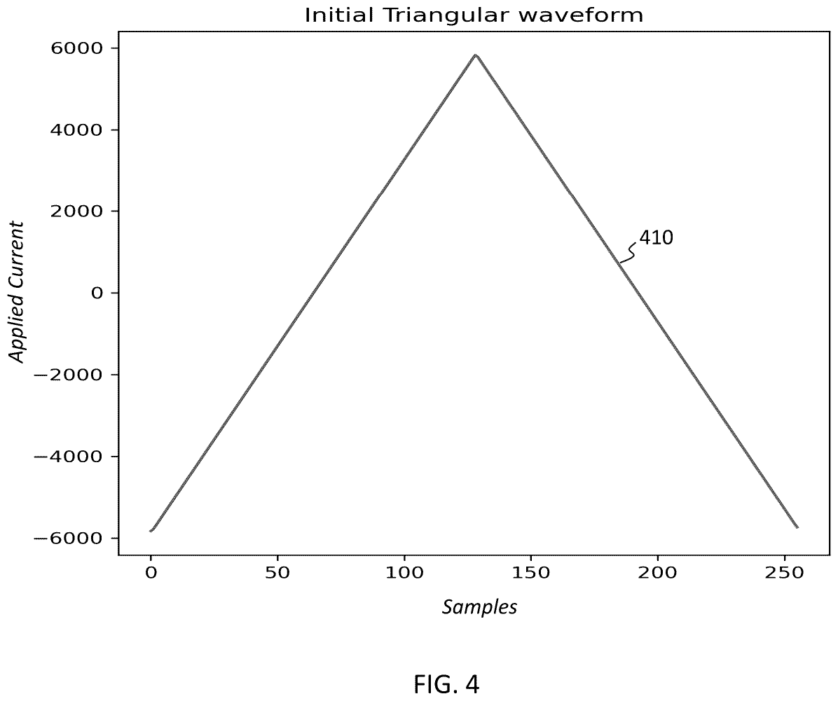

FIG. 4 illustrates a typical starting beam scanning waveform. Specifically, FIG. 4 shows a purely triangular waveform depicted in an X-Y diagram, where the X-axis represents the number of samples in the waveform and the Y-axis represents the current applied to the scan magnet which determines the horizontal displacement of the beam location. In this example the number of samples on the X-axis can be converted to time via the scanning frequency used by the implantation system. The derivatives at each point of the waveform 410 represent the speed of the change of the current in the scanner (constant speed for the triangle waveform) as it moves the beam from side to side with respect to the workpiece. In an exemplary application of the disclosed principles, autotuning is initiated substantially with the triangular waveform of FIG. 4. In one embodiment, the scan waveform may have a fixed number of samples regardless of frequency and frequency may be changed by changing the sample duration in the waveform rather than the number of samples.

As discussed, conventional methods rely on data collected by one or more traveling beam current measurement devices (i.e., profiler faradays) to determine the beam current density profile within the area of a workpiece. The implantation system will conventionally us this data to calculate a set of adjustments to the beam control system (e.g. DC magnet currents and power supply voltages or AC waveforms for magnetic or electrostatic scanning systems) expected to meet the recipe limits on the matching of the beam current density profile to a desired profile. In this context, the collected data comprises the input signals. Conventional methods rely on the time-consuming physical movement of one or more traveling beam current measurement devices before attempting to generate the adjustments to the beam control knobs to achieve the desired beam current density profile. The conventional methods are time consuming because of their reliance on the physical travel duration of the measurement device. In certain disclosed principles, data from one or more stationary beam current measurement devices (e.g., faradays, power supply currents, etc.) are used to determine a set of adjustments (e.g. a modified waveform for the beam scan system) before the physical motion of any measurement device is required. The input signals are translated to a target set of adjustments via the AI model and these adjustments are applied to the beam tuning control system by the ion implantation equipment.

The disclosed principles sample the input signals from one or more stationary measurement devices at a high frequency (in one embodiment, 250 KHz) are synchronized with the signal controlling the motion of the of the ion beam and are provided to an AI model to predict the necessary adjustments to the tuning of the ion beam to meet the desired beam current density profile (for example, the output of the AI module may be a waveform applied to the beam scanning system to adjust the relative dwell time at different locations across the scanning of a spot ion beam) within a the region of interest. The disclosed principles advantageously detect the time dependent beam current variations as opposed to a single average beam current measurement over a scan period. Because data is collected from the stationary beam current measurement devices, the time spent moving a traveling measurement device is avoided to provide a faster feedback loop of adjusting the ion beam tuning controls and predicting the impact to the beam current density profile in the region of interest thus reducing the total setup time. Stated differently, a conventional method such as dynamic markers use high speed (e.g., 250 kHz), time synchronized data from a traveling profiler Faraday to calculate a target waveform to apply to the beam scanning system to achieve a desired beam current density profile in the region of interest. To make the calculation, the profiling faraday must collect beam current density measurements at a significantly high spatial density across the region of interest to determine the beam current density profile that will be implanted into the workpiece while moving slowly enough to collet at least one full beam scan period at each profiler location so that the waveform adjustments can be calculated. . . . In the disclosed embodiments, instead of moving a traveling Faraday to collect data at multiple (typically in the range of hundreds or thousands of locations) locations across the region of interest (to get a comprehensive set of beam current density profiles from which the waveform can be derived), a smaller number of stationary beam current measurement devices are positioned at locations which cover the same or larger area as the profiler would have traveled to collect the input signals which the AI model will use to predict the adjustments to the beam tuning controls necessary to achieve the desired beam current density profile. This results in a significant reduction of the setup time.

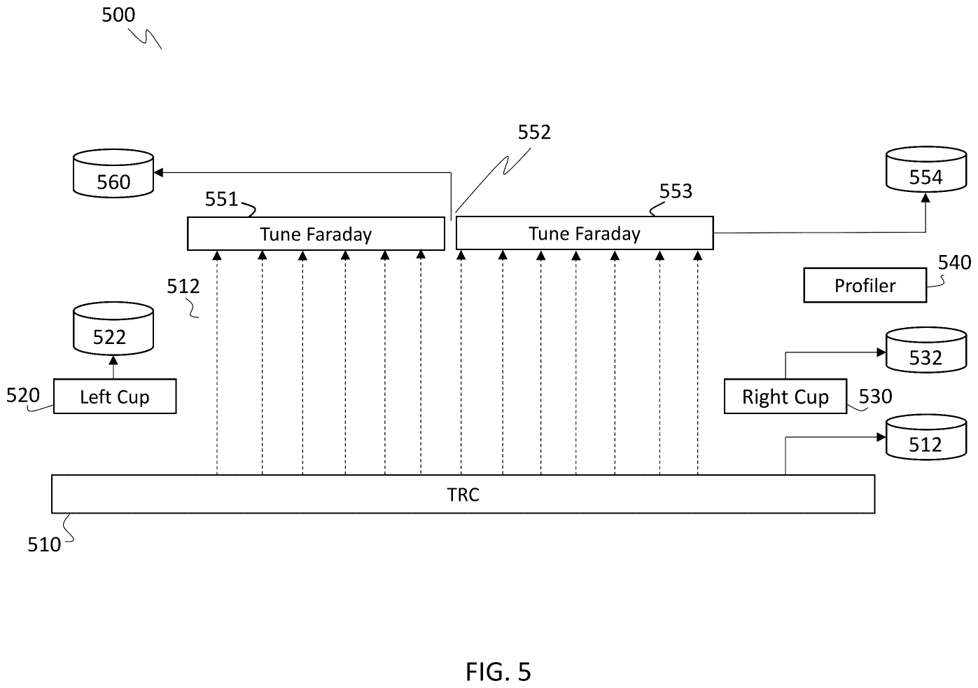

FIG. 5 is a schematic representation of an exemplary process chamber according to one embodiment of the disclosure. Process chamber 500 of FIG. 5 may be implemented as an end station (e.g., end station 116 of FIG. 1). Process chamber 500 of FIG. 5 comprises a Terminal Return Current measurement (TRC) 510 at a location where the ion beams 512 enter the process chamber. The TRC may define a power supply readback. FIG. 5 shows TRC 510 which may be optionally positioned at the exit of corrector magnet (angle parallelization magnet 160, FIG. 1) or at the entrance to process chamber 500. In one embodiment, the TRC measures the electron current circulating from the terminal to ground as a result of ion beam current exiting the terminal region (making this power supply current an indirect beam current measurement) and this measured beam current response is stored in database 512.

Two beam current measurement devices (e.g., Tune Faradays) 551, 553 are positioned to receive scanned ion beam 512 which traverses left to right and right to left. Measurement devices 551 and 553 may be measured independently or summed either in software or by electrically bonding the two collectors to one another. Center opening contains another beam current measurement device 552 (e.g., center strip faraday) which is located between measurement devices 551 and 553. While the exemplary embodiment of FIG. 5 shows only a single opening 552 (strip faraday), having multiple openings with multiple narrow measurement devices (multiple strip faradays) between multiple other beam current measurement devices (additional faraday segments) is within the scope of the disclosed principles. In one application, opening 552 acts as a sensor (center cup) for measuring flux values at the center of process chamber 500. The data from opening 552 is stored at central tune cup database (interchangeably, memory circuitry) 560. Tune measurement devices 551 and 553 receive the ion beam 512 and collect beam characteristics measurements (e.g. time varying beam current measurements). The data is stored in database 554. Similarly, the left beam current measurement device 520 and the right beam current measurement device 530 receive scanned beam 512 and store the relevant beam characteristics data at databases 522 and 532, respectively. In one embodiment, data is sampled at the various stationary beam current measurement devices at a rate of about 250 KHz (higher and lower frequency are also considered within this disclosure). The samples may be obtained synchronously with any time varying command signal applied to move the beam partially or fully across the measurement devices.

To improve tool throughput and efficacy, it is important to minimize the time spent tuning the ion beam by reducing time lost to iterative steps of adjusting beam control knobs and measuring the beam current density profile in the area of the workpiece. Various real-time signals can be processed to predict or generate the set of adjustment to the ion beam controls that may simultaneously meet beam setup and process specifications without the necessity to move a traveling beam current measurement device. By starting with the predicted set of beam tuning controls instead of a default (or the last known good set of controls), more setups may meet the specified limit the first time the beam is measured with the traveling profiler. When additional iterations are needed the beam current density profile will start closer to the desired profile reducing the total number of iterations and thus reducing the total number of times that the traveling measurement device must move. If the initially generated set of beam tuning controls does not produce the desired beam current density profile as validated by the traveling measurement device, the data collected from this traveling measurement device may be used to supplement the data from the stationary beam current measurement devices in subsequent iterations generating a new set of adjustments to the beam tuning control knobs.

In the exemplary embodiment of FIG. 5, traveling profiler 540 may measure the beam current density profile in the region of interest. In one application of the disclosed principles, the scanned beam is received by the stationary beam current measurement devices and its characteristics are determined and stored at the respective databases. This information is then evaluated by the regenerative AI, residing for example, at a control system (e.g., control system 154, FIG. 1). The information is then used to drive or generate a set of adjustments to beam tuning controls which are provided to and implemented by the control system (for example, a waveform may be applied to the scanner) to modify the beam current density profile in a region of interest to match a desired density profile. Once the predicted adjustments are applied to the control system (e.g., 154), the profiler 540 is moved to a position to intercept scanned beam 512 and measures its beam characteristics to confirm the new beam current density profile. The disclosed AI generative model generates the predicted adjustments to beam tuning controls from the input signals which include only data from stationary measurement devices at the first iteration and are augmented with data from any measurements collected by the traveling beam current measurement device (e.g. profiler 540). If the beam current density profile measured by the traveling device matches the desired profile with a specified limit on the first measurement then subsequent adjusts to the beam tuning controls are not necessary and the control system may skip ahead to other beam tuning steps or on to the processing of a workpiece.

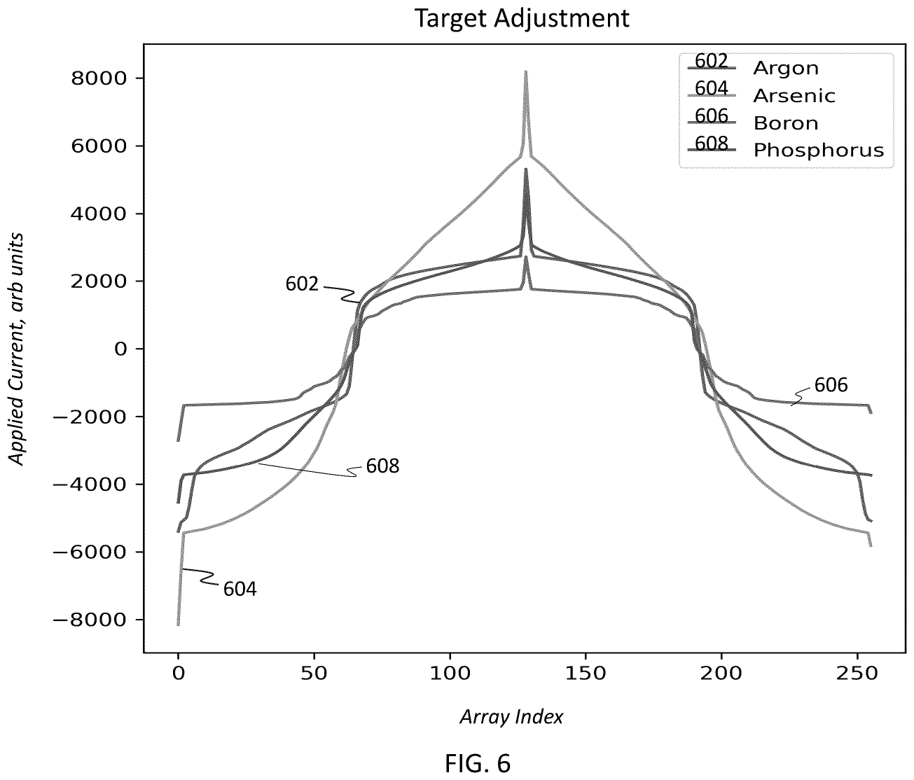

FIG. 6 shows several exemplary waveforms which are calculated as beam tuning adjustments in one embodiment obtained using the disclosed principles. The beam current density profile in the region of interest produced by applying the waveforms of FIG. 6 may be measured by using beam current measurement device 551, 553 and Profiler 540 of FIG. 5. Once the beam tuning control adjustments (shown as waveforms in FIG. 6) are obtained, they may be further modified according to the generative methods disclosed herein, to achieve the desired beam current density profile.

The x-axis of FIG. 6 shows the index of each of the samples provided to the scan system to translate the ion beam in the horizontal direction. The waveform is shown in this generalized form such that the same waveform may be used at different frequencies simply by changing the duration of each sample across the index. The y-axis represents the analog to digital (ADC) counts which are supplied to the scan system (136A, 136B of FIG. 1) to apply as a current to coils in the magnet producing a magnetic field to displace the ion beam. The negative portion of the y-axis indicates that the beam is moved to the right of the center of the workpiece (as viewed by the impinging ion beam) and the positive portion of the y-axis means that the beam is moved to the left of the center of the workpiece. Thus, the scanned ion beam is moving in response to the waveform depicted in FIG. 6. In one representation, derivative of the scan magnet current with respect to time (dl/dt) determines the relative dwelling period of the beam at various locations in the region of interest where lower dI/dt results in slower motion of the beam at that location raising the dose relative to constant ion beam horizontal scan speed. Conversely, high dI/dt results in fast movement of the beam at that location reducing the local beam current density and thus lowering the implanted dose.

FIG. 6 also shows the set of tuning control adjustments (e.g. predicted waveforms) which have been generated for implantation of argon 602, arsenic 604, boron 606 and phosphorus 608 ion beams. In one embodiment of the disclosure, a predicted waveform depicted in FIG. 6 may be used as the starting point for the implantation process based on the material being implanted.

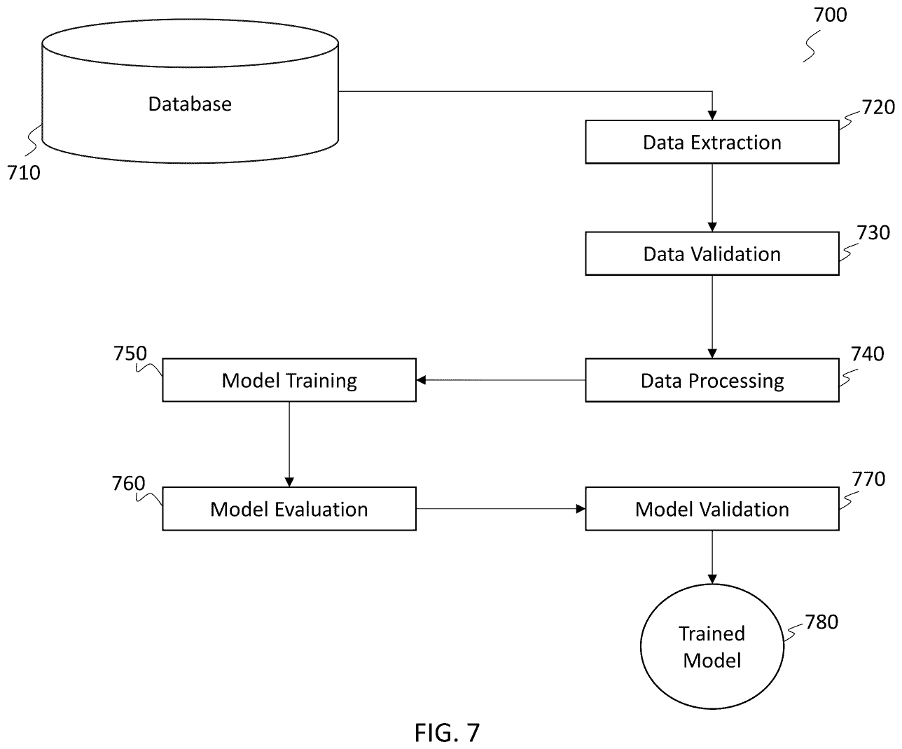

FIG. 7 is a schematic representation of an exemplary AI training process according to one embodiment of the disclosure. Specifically, system 700 of FIG. 7 shows an exemplary embodiment for saving data obtained from the sensors of FIG. 6. Data may be stored locally (i.e., on the instrument), remotely (i.e., the fog or the cloud) or both as illustrated by database 710. Next, data is extracted from database 710 as shown at operation 720. The extracted data is then validated at operation 730. Data validation may have many forms, In one aspect of the disclosure, data validation may include filtering data to remove noise or identifying and correcting for the missing input signal data.

Data processing operation 740 includes conventional data processing steps including data normalization, data standardization, further data cleansing and noise reduction. Each step may be augmented with additional sub steps to ensure that the data used for the AI model training is accurate, consistent and representative.

The processed data is then used for model training as denoted at operation 750. Model training may comply with conventional deep neural network training methods. In an exemplary embodiment, several thousand sets of input signals from the implanter may be provided as input to the deep neural network layers (not shown). In an exemplary embodiment, a generative model based on deep neural network training such as the Generative Adversarial Networks (GANS), Transformer, Bayesian method and Deep Reinforcement Learning may be used to generate new data (e.g., predicted adjustments to beam tuning controls including but not limited to waveforms applied to beam scanning systems).

At operation 760, the model is evaluated and at operation 770 the model is validated. At operation 780, the trained model is made available for application to force the ion beam current density profile to converge to the desired target beam current density profile. If the model fails to validate, additional datapoints may be obtained and the process repeated until the desired training model 780 is obtained.

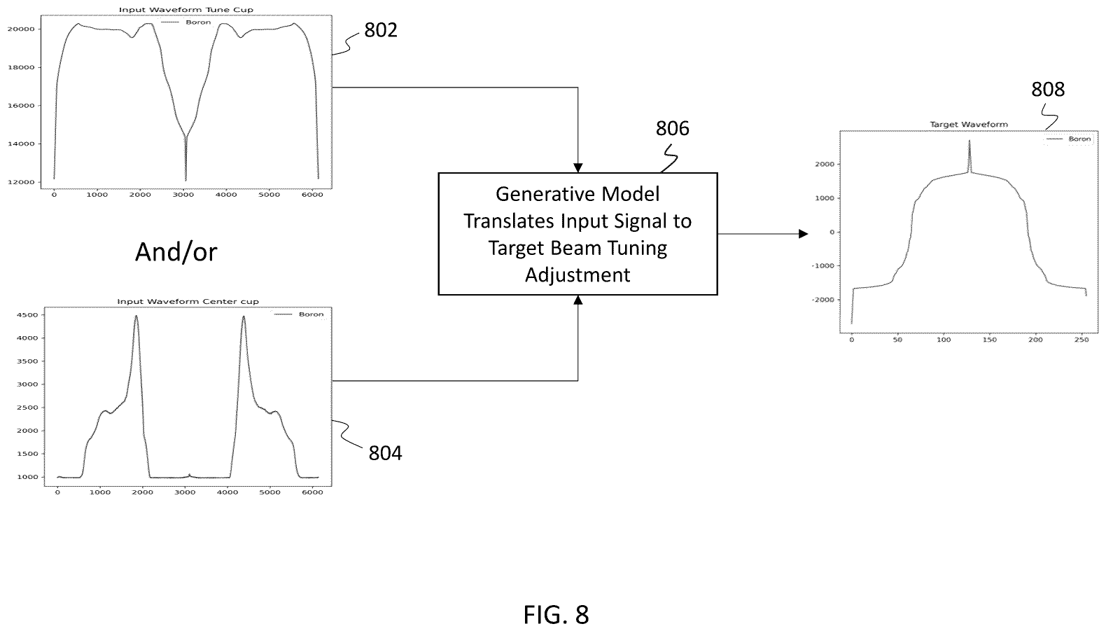

FIG. 8 schematically illustrates an application of certain disclosed principles to obtain a set of beam tuning control adjustments from stationary beam current measurement devices. In the exemplary embodiment of FIG. 8 and with reference to FIG. 5, data obtained from stationary beam current measurement devices including tune faradays (551, 553), central tune strip faraday (552), TRC (510), left dose faraday (520), right dose faraday (530) or other current measurement devices can be used as input signals to the AI generative model to predict a set of beam tuning control adjustments. In one embodiment of the disclosure, the input signal can be extracted from a singular measurement device. In another embodiment, two or more input signals are combined and provided to the AI model for generating the predicted beam tuning adjustments. In still another embodiment, the AI model selects from among a plurality of the input signals.

The axis of each of representations 802, 804 and 808 are similar to those in FIG. 6. In the embodiment of FIG. 8, signal 802 represents the input signal as a waveform obtained from a centrally located beam current measurement device and signal 804 represents the input signal as a waveform obtained from the strip faraday located between 551 and 553 in FIG. 5. Both signals 802 and 804 are waveforms derived by synchronizing measurements from the stationary beam current measurement devices with the control signal for the motion of the beam across these devices and the region of the workpiece. AI generative model 806 receives the input signals and translates them into an output which is a set of adjustments to beam tuning controls such as the predicted waveform to be provided to the scan system illustrated as 808. In one embodiment of the disclosure, the generative model uses a combination of the input signals. In another embodiment, the generative model selects from among the incoming signals. The AI generative model may use GANS, Deep Reinforcement Learning or auto-encoder transformers or any other machine learning model to generate the predicted beam tuning adjustments. In another embodiment of the disclosure, the GAN is also used with Deep Reinforcement learning, Transfer and deep learning models. The predicted beam tuning control adjustments 808 is the output of the AI generative model and may be a waveform or may be discrete changes to beam tuning controls. Once the predicted adjustments are generated, the ion implantation control system will apply the changes 808 to the appropriate beam tuning controls. By starting the tuning process with tuning setting 808 that are predicted to simultaneously satisfy all recipe specifications the time to setup the implant process in compliance with these specifications is substantially reduced.

In certain embodiments, the generation of the predicted beam tuning control settings occurs in the order of nanoseconds. Highspeed data profiles are taken synchronously by stationary beam current measurement devices and collected at a predetermined frequency (for example, 250 KHz). The time necessary to collect a single sample from any of the stationary devices is determined primarily by the time it takes to displace the ion beam across said devices (for example, if the ion beam is scanning at 81 Hz a single scan period will be on the order of 0.0123 seconds thus making this the minimum time to collect the sample from the beam current measurement device). The disclosed beam scanning frequency is exemplary and may be increased or decreased without departing from the disclosed principles.

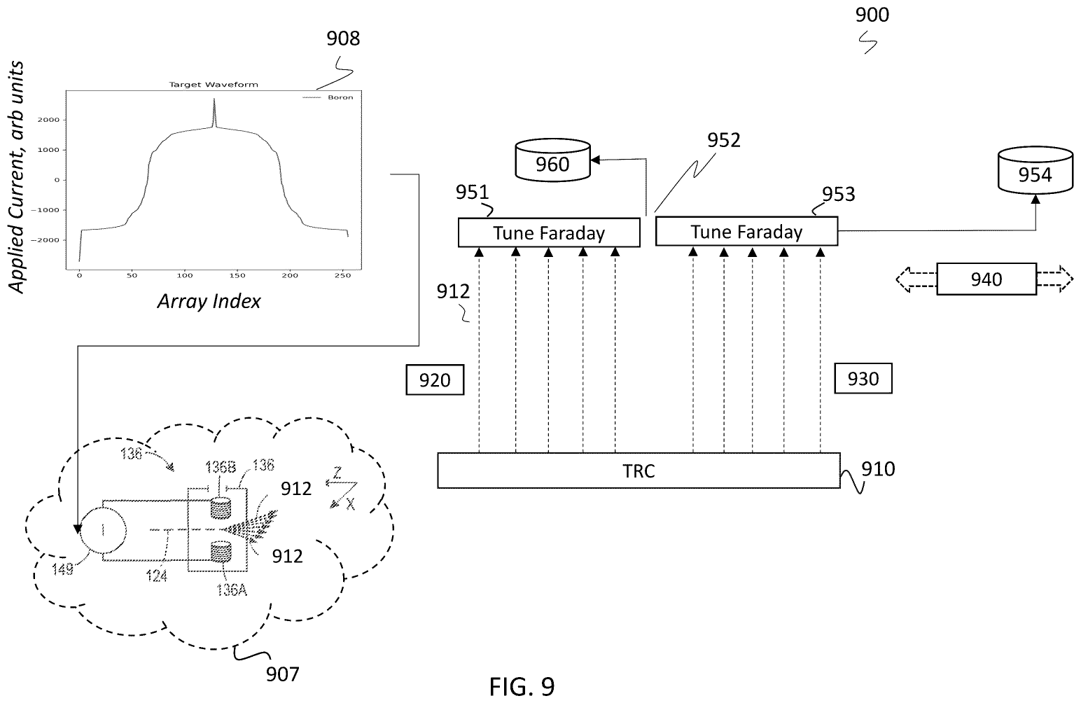

FIG. 9 schematically shows an exemplary embodiment of the disclosure in which an AI generated set of beam tuning controls (e.g., beam scanning waveform 908) is applied to the appropriate control (e.g., the scan system 907 in the case of a scanning waveform) in order to change the beam current density profile in the region of the workpiece. Specifically, in one embodiment the beam tuning adjustments are a target scanning waveform 908 which is the output of the AI generative model obtained according to one embodiment of the disclosed principals. After the beam tuning controls are set per AI model output (908) and the beam current density in the area of the workpiece is confirmed, the beam current signals from the stationary measurement devices (such as TRC 910, left side mounted faraday 920, right side mounted faraday 930) may be collected, synchronized with the motion of the ion beam and set as references. The control system may then periodically collect signals from the beam current measurement devices while processing workpieces and compare them against the previously established references. Drift in the ion beam motion synchronized current measurements may be used either for real-time recalculation and adjustment of beam tuning controls or alternatively to interlock and pause workpiece processing to confirm the quality of the ion beam before resuming workpiece process. FIG. 9 shows a left mounted faraday 920, right mounted faraday 930, traveling (profiler) faraday 940 as well as centrally mounted tune faradays 951, 953. Slit 952 is also denoted in FIG. 9. The power supply current TRC 910 is also shown. For simplicity only databases 960 and 954 are represented in FIG. 9. The disclosed principles are not dependent on the beam current measurement devices being implemented either as faradays or as power supply current readbacks.

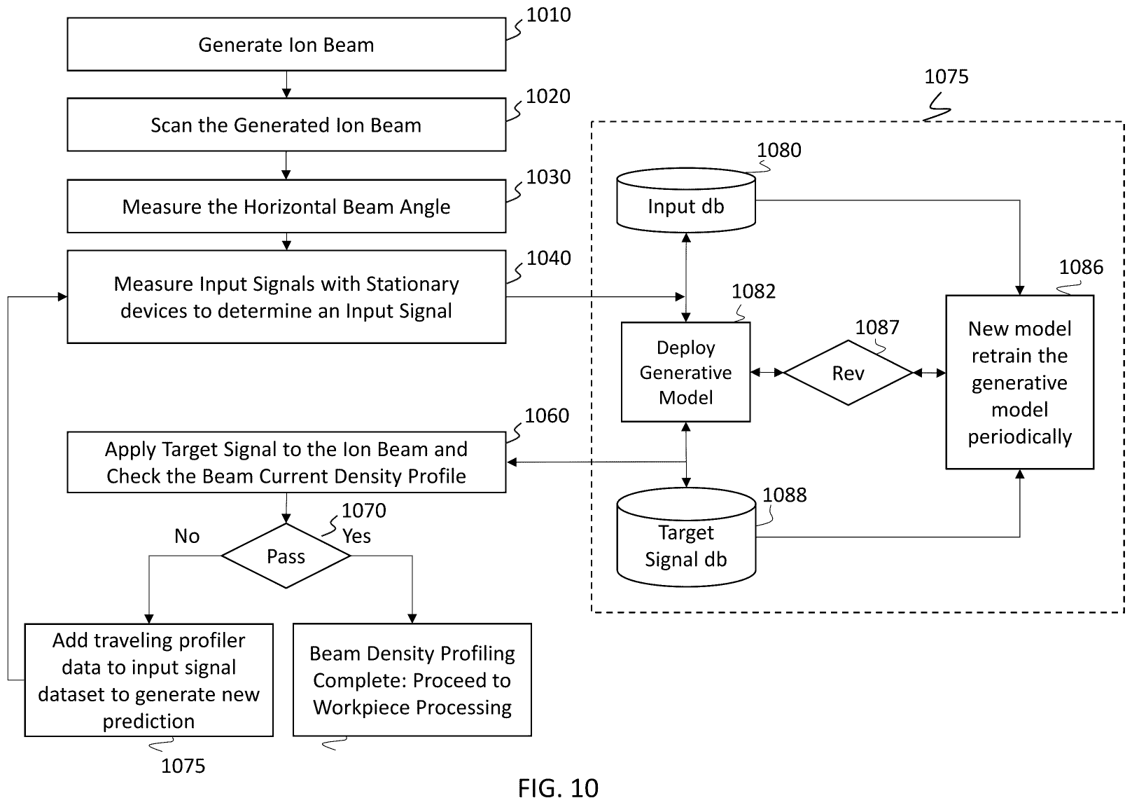

FIG. 10 schematically illustrates a process flow diagram for continuously collecting data and updating the AI generative model. The process of FIG. 10 may be implemented on the instrument (not shown) or may be stored and implemented remotely (e.g., cloud implementation). The process of FIG. 10 may be implemented at a processor circuitry (not shown) in communication with one or more memory circuitries (not shown). The processor circuitry may comprise one or more Central Processing Units (CPUs) in communication with the memory circuities, the sensors (including but not limited to Faradays), the ion-generating terminal and power supply. The memory circuitries may comprise instructions to retain the processes depicted in FIG. 10 and communicate the instructions to the controller upon request. The instructions may be stored on one or more memory circuitries. The controller may then execute the instructions on the ion implantation instrument. In one embodiment, the controller circuitry and the memory circuities may be defined in the control system (e.g., control system 154, FIG. 1).

The process of FIG. 10 starts at operation 1010, by generating an ion beam. The generated ion beam is then scanned at operation 1020 as discussed in relation to FIG. 1. At operation 1030, the horizontal beam angle (HBA) of the ion beam is measured and the necessary adjustments may be made. The measurement and adjustment of the HBA is an optional step and may be completed in conjunction with or independently from measurements of the vertical angle (VBA). If angle data is collected at operation 1030, it may be stored and used as an input signal along with data collected at operation 1040. At operation 1040 the input signals are measured using one or more stationary beam current measurement devices and synchronized with the control signal applied at operation 1020. The measured input signals are then communicated to input database 1080 and to the generative model 1082. Input database may store the various measured input signals from the respective plurality of stationary beam current measurement devices and the synchronized controls applied at operation 1020. Each input signal data may be associated with time, location, implantation material, intensity and any other information available to the implantation control system about the requested ion implantation process.

Input database 1080 may communicate this and other information to processor circuitry 1086 to form a new generative AI model for improved prediction of the appropriate settings for the beam tuning controls (such as scanning waveform). Processor 1086 may retain the existing regenerative model or may form a new model periodically and according to a set of predefined machine learning (ML) instructions. When generated, the new model may be communicated to decision processor 1087 to determine whether to deploy the new model or to retain the existing generative model. The decision processor 1087 may consider different variables in this determination. By way of example, the determination may be made based on observed trending of the predicted adjustments or based on one or more predefined performance thresholds. In one embodiment, an authorized operator may have the option to approve or reject the implementation of the new model. In certain embodiments, a new AI model may be generated periodically without human involvement. The model deployment is shown at operation 1082, which may be considered as a so-call generative portal. The predictions of the generative model, which are a set of beam tuning controls (such as a target scanning waveform), is then added to target signal database 1088. In addition, the new beam tuning controls may be applied directly to the ion beam (e.g., ion beam 124, FIG. 1 or ion beam 912, FIG. 9) as shown in operation 1060 and the beam current density profile is measured in the region of the workpiece. At operation 1070 the implantation system determines if the beam current density profile is matched closely enough to the desired profile to complete tuning and begin workpiece processing. If the observed beam current density profile does not match the desired profile the system may add the data from the traveling faraday to the inputs of the generative model or may be configured to apply convention tuning methods or deep reinforcement learning for further tuning of the beam current density profile as schematically illustrated at operation 1075. If the observed beam current density profile does not match the desired profile, then the beam density profiling is complete and the operation turns processing the workpiece. The subroutine depicted as 1075 may be continually implemented at the instrument or on a network to predict changes to the beam current density profile and predict appropriate changes to the beam tuning controls even if real time adjustments to the controls are not enabled during workpiece processing. The process enables continual storage of scanning and implantation data, which in turn, allows for enhanced ML training of the AI system.

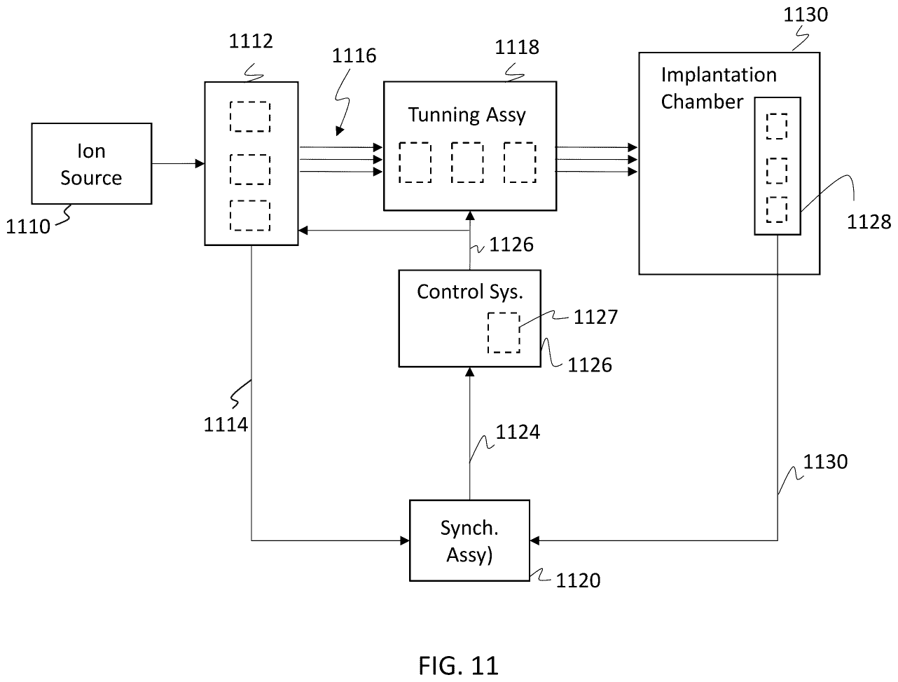

FIG. 11 schematically illustrates an exemplary system for implementing an embodiment according to the disclosed principles. The components of FIG. 11 are described in relation to FIG. 1, in which ion source assembly 1110 may be a power supply (122, FIG. 1), terminal or ion generation chamber (121, FIG. 1) and an electrode pair (125A and 125B, FIG. 1). Beamline assembly 1112 displaces the ion beams generate by ion source assembly 1110. Beamline assembly 1112 may comprise subassemblies including, for example, mass analyzer subassembly (126, FIG. 1), beam guide subassembly (132, FIG. 1), beamline focusing and steering subassembly (138A and 138 B, FIG. 1) and scanner subassembly (136, FIG. 1). For simplicity, subassemblies of FIG. 11 are represented with dashed lines. Beamline assembly 1112 generates control signal 1114 for beamline displacement and communicates the control signal 1114 to synchronization assembly.

Tuning assembly 1118 receives scanned ion beamline 1116 (124, FIG. 1) and adjusts certain controllable subassemblies to tune the beamline according to desired controls. Tuning assembly 1118 may comprise one or more subassemblies configured to tune, among others, the intensity, shape and position of the ion beam current density. The tuning subassemblies may include, for example, control mechanism for tuning a DC magnet current or DC voltage (e.g., 122, FIG. 1) or alternatively adjusting an AC scanner waveform magnetically or electrostatically along (149 and 150, FIG. 1). Additional tunning knobs may tune dipole magnet subassembly 139A and 139B, FIG. 1), deceleration subassembly (157A and 157B, FIG. 1) and charge neutralization subassembly (160, FIG. 1).

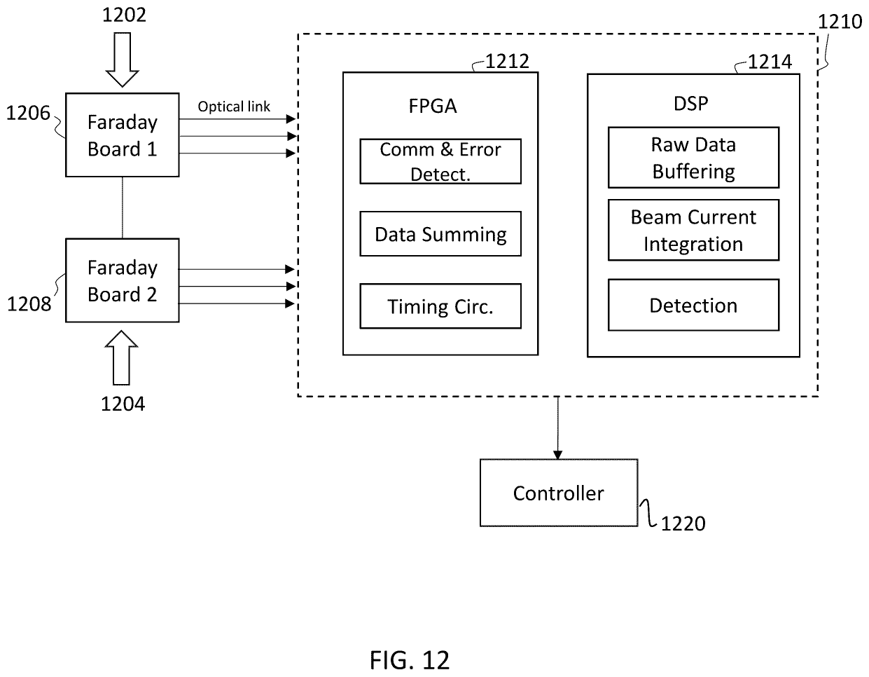

Synchronization assembly 1120 may be configured to generate input signal 1124 by synchronizing one or more beam current density measurements 1130 received from the stationary sensor assembly 1128 and control signal for beamline displacement 1114. Synchronization assembly 1120 may comprise one or more Field-Programmable Gate Array (FPGA) firmware to implement synchronization of the received signals 1114 and 1130. It should be noted that beam current density measurement signal 1130 may comprise multiple channels which correspond to each of the multiple stationary sensors. The exemplary FPGA is discussed further below in relation to FIG. 12.

Referring again to FIG. 11, sensor assembly 1128 may comprise one or more stationary sensors as schematically illustrated by dashed boxes. Synchronization assembly 1120 synchronizes signals 1114 and 1130 to form input signal 11124. Control system 1126 (e.g., 154, FIG. 1) receives input signal 1124 from synchronization assembly 1120 and translates the input signal to predicted control settings 1132. In one embodiment, predicted control settings 1132 define a waveform which may be applied to the corresponding subassemblies to adjust scanning of ion beam 1116. Control system 1126 may comprise generative AI system 1127 according to the disclosed embodiments in order to generate the predicted control settings. Once applied, predicted control settings 1132, modify the beam current density profile 1119 and apply the same in the region of the workpiece (not shown) in implantation chamber 1130.

FIG. 12 schematically illustrates a simplified synchronization architecture according to one embodiment of the disclosure. Input 1202 may comprise signal inputs from a first set of sensors (e.g., tune Faraday, front profiler, rear profiler). Input 1204 may comprise inputs from a second set of sensors (e.g., left Faraday, right Faraday and the VBA sensors). While the inputs are shown independently, they may be combined into one input. Each of Faraday processing boards 1206 and 1208 communicates the data via optical links to the FPGA/DSP subsystem 1210 which includes FPGA 1212 and digital signal processing (DSP) circuit 1214, FPGA 1212 is shown with exemplary processing circuits for communication and error detection, data summation and timing/interrupt circuits. DSP 1214 is shown with raw packet buffering circuit, beam current integration circuit and glitch detection circuit. These circuits are exemplary and non-limiting of the disclosed principles. The output from the FPGA/DSP subsystem 1210 is provided to controller 1220 for generative AI processing. Additional components may be added as needed to the embodiment of FIG. 12 without departing from the disclosed principles.

The disclosed embodiments are advantageous in that beam current density profile tuning can be implemented in a fraction of the time of the conventional methods. Moreover, the disclosed embodiments are not recipe-dependent; thus, prior knowledge of the implantation process is not required. The disclosed embodiments also provide for continuous monitoring and updating the model. In certain applications, the disclosed embodiments can handle signal deviations caused by repair (or part replacement) of hardware parts as the AI continuously updates the datasets and retrains itself periodically.

### Additional Notes & Examples

The following exemplary and non-limiting embodiments are provided to further illustrate the disclosed principles.

Example 1 is directed to an ion implantation system, comprising: an ion source configured to generate an ion beam having an ion beam current density; a beamline assembly having one or more subassemblies configured provide a control signal to displace the ion beam in a direction orthogonal to the direction of motion of the implantation workpiece; a sensor assembly comprising one or more stationary sensors configured to conduct one or more beam current density measurements as the ion beam is displaced thereacross; a synchronization assembly configured to synchronize the beam current density measurements from the stationary sensors with the control signal for ion beam displacement; one or more tuning subassemblies to tune the intensity, shape and position of the ion beam current density; a control system in communication with the one or more tuning subassemblies, the control system configured to: receive an input signal, the input signal comprising an input waveform generated by synchronizing the measured beam current density from the one or more stationary sensors with the control signal from the beamline assembly; generate a set of predicted control settings for the tuning subassemblies from the input signal; and communicate the predicted control settings to the tuning assemblies to adjust the beam current density profile in a region of a workpiece.

Example 2 is directed to the ion implantation system of example 1, wherein the control system further comprises an artificial intelligence (AI) process circuitry configured to apply one or more of generative adversarial networks (GANS), autoencoder transformer, deep reinforcement learning, deep neural networks or curve force fitting to generate the predicted set of beam tuning control settings.

Example 3 is directed to the ion implantation system of example 1, further comprising a beam sampling system to measure the horizontal beam angle (“HBA”) and or vertical beam angle (“VBA”) of the ion beam.

Example 4 is directed to the ion implantation system of example 1, wherein the one or more stationary sensors further comprise a side mounted Faraday, a central tuning Faraday, and one or more independently monitored Faraday slits positioned across the beam scanning area.

Example 5 is directed to the ion implantation system of example 1, wherein the one or more stationary sensors further comprise a power supply readback to monitor the Terminal Return Current (TRC), Beam Tunnel Current and other sources communicating power to electrodes along the beamline.

Example 6 is directed to the ion implantation system of example 1, wherein the control system is further configured to apply the predicted control setting to any assemblies or subassemblies to the transport, shape or change trajectory of the ion beam to thereby modify the beam current density profile in the region of the workpiece.

Example 7 is directed to the ion implantation system of example 1, wherein the control system is further configured to receive a beam current density profile measurement from a traveling Faraday in the region of the workpiece.

Example 8 is directed to the ion implantation system of example 1, wherein the control system further comprises a memory circuitry for storing the input signals received from the stationary sensors and a processor circuitry in communication with the memory circuitry to generate the set of predicted control settings for the tuning subassemblies,

Example 9 is directed to a method for beam uniformity correction in an ion implantation system, the method comprising: generating an ion beam; applying a control signal to displace the ion beam in a direction orthogonal to the direction of motion of an implantation workpiece; receiving an input signal from one or more stationary sensors configured to measure the ion beam current density, wherein the input signal comprises an input waveform generated by synchronizing the beam current density signals from the one or more stationary sensors with the control signal; generating a set of predicted control settings for beam tuning, wherein the predicted control settings affect one or more of intensity, shape and position of the ion beam; applying the predicted control settings to adjust the beam current density profile in the region of a workpiece.

Example 10 is directed to the method of example 9, further comprising a method to measure the horizontal beam angle (“HBA”) and or vertical beam angle (“VBA”) of the ion beam.

Example 11 is directed to the method of example 9, wherein generating a set of predicted control settings further comprises applying an artificial intelligence (AI) process including one or more of generative adversarial networks (GANS), autoencoder transformer, deep reinforcement learning, deep neural networks or curve force fitting.

Example 12 is directed to the method of example 9, further comprising collecting current beam density measurement valued from one or more side mounted measurement sensors, centrally located tuning beam current measurement sensor, and one or more independently monitored beam current measurement sensor slits positioned across from the implantation workpiece.

Example 13 is directed to the method of example 9, further comprising collecting beam current density measurement values from a power supply readback, from a power supply biasing the Beam Tunnel and from a sensor positioned to detect a current change due to ion beam position change.

Example 14 is directed to the method of example 13, wherein the power supply readback comprises a Terminal Return Current (TRC).

Example 15 is directed to the method of example 9, further comprising sampling the ion beam with a traveling beam current measurement device to obtain a direct measure of the beam current density distribution in the region of the workpiece.

Example 16 is directed to a non-transitory, computer readable storage medium containing instructions stored thereon that, when executed, implement a method of implementing automatic beam current density distribution tuning for an ion implantation system on an implantation workpiece, the instructions comprising: generating an ion beam; displacing the ion beam in a direction orthogonal to the direction of motion of the implantation workpiece through a control signal; obtaining an input signal from one or more stationary sensors configured to detect an ion beam current density value, wherein the input signal comprises an input waveform generated by synchronizing the beam current density signal from the one or more stationary sensors with the control signal; generating a set of predicted control settings for beam tuning, wherein the predicted control settings affect one or more of intensity, shape and position of the ion beam; applying the predicted control settings to adjust the beam current density profile in a region of the workpiece.

Example 17 is directed to the medium of example 16, the instructions further comprising measuring the one or more of horizontal or vertical beam angles associated with the ion beam and applying the measurements to generating the set of predicted control settings.

Example 18 is directed to the medium of example 16, wherein generating a set of predicted control settings further comprise applying an artificial intelligence (AI) process including one or more of generative adversarial networks (GANS), autoencoder transformer, deep reinforcement learning, deep neural networks or curve force fitting to thereby generate the predicted settings for the beam tuning controls.

Example 19 is directed to the medium of example 16, the instructions further comprising collecting signals from at least one of a side mounted beam current measurement device, a centrally located tuning beam current measurement device, and an independently monitored beam current measurement device slits positioned across the area of the workpiece.

Example 20 is directed to the medium of example 16, the instructions further comprising collecting signals from one or more of a power supply readback, a current readback from a power supply biasing a Beam Tunnel and any sensor sensitive to ion beam current change arising from the ion beam's position change.

Example 21 is directed to the medium of example 16, the instructions further comprising further modifying the predicted tuning control settings to adjust the beam current density distribution in the region of the workpiece.

Example 22 is directed to the medium of example 16, the instructions further comprising sampling the ion beam with a traveling beam current measurement device to directly measure the beam current density distribution in the region of the workpiece.

Although embodiments of the invention have been described in language specific to structural features and/or methodological acts, it is to be understood that claimed subject matter may not be limited to the specific features or acts described. Rather, the specific features and acts are disclosed as sample forms of implementing the disclosed principles.

What is claimed is:

1. An ion implantation system, comprising:
an ion source configured to generate an ion beam having an ion beam current density;
a beamline assembly having one or more subassemblies configured provide a control signal to displace the ion beam in a direction orthogonal to the direction of motion of the implantation workpiece;
a sensor assembly comprising one or more stationary sensors configured to conduct one or more beam current density measurements as the ion beam is displaced thereacross;
a synchronization assembly configured to synchronize the beam current density measurements from the stationary sensors with the control signal for ion beam displacement;
one or more tuning subassemblies to tune the intensity, shape and position of the ion beam current density;
a control system in communication with the one or more tuning subassemblies, the control system configured to:
receive an input signal, the input signal comprising an input waveform generated by synchronizing the measured beam current density from the one or more stationary sensors with the control signal from the beamline assembly;
generate a set of predicted control settings for the tuning subassemblies from the input signal; and
communicate the predicted control settings to the tuning assemblies to adjust the beam current density profile in a region of a workpiece.

2. The ion implantation system of claim 1, wherein the control system further comprises an artificial intelligence (AI) process circuitry configured to apply one or more of generative adversarial networks (GANS), autoencoder transformer, deep reinforcement learning, deep neural networks or curve force fitting to generate the predicted set of beam tuning control settings.

3. The ion implantation system of claim 1, further comprising a beam sampling system to measure the horizontal beam angle (“HBA”) and or vertical beam angle (“VBA”) of the ion beam.

4. The ion implantation system of claim 1, wherein the one or more stationary sensors further comprise a side mounted Faraday, a central tuning Faraday, and one or more independently monitored Faraday slits positioned across the beam scanning area.

5. The ion implantation system of claim 1, wherein the one or more stationary sensors further comprise a power supply readback to monitor the Terminal Return Current (TRC), Beam Tunnel Current and other sources communicating power to electrodes along the beamline.

6. The ion implantation system of claim 1, wherein the control system is further configured to apply the predicted control setting to any assemblies or subassemblies to the transport, shape or change trajectory of the ion beam to thereby modify the beam current density profile in the region of the workpiece.

7. The ion implantation system of claim 1, wherein the control system is further configured to receive a beam current density profile measurement from a traveling Faraday in the region of the workpiece.

8. The ion implantation system of claim 1, wherein the control system further comprises a memory circuitry for storing the input signals received from the stationary sensors and a processor circuitry in communication with the memory circuitry to generate the set of predicted control settings for the tuning subassemblies.

9. A method for beam uniformity correction in an ion implantation system, the method comprising:
generating an ion beam;
applying a control signal to displace the ion beam in a direction orthogonal to the direction of motion of an implantation workpiece;
receiving an input signal from one or more stationary sensors configured to measure the ion beam current density, wherein the input signal comprises an input waveform generated by synchronizing the beam current density signals from the one or more stationary sensors with the control signal;
generating a set of predicted control settings for beam tuning, wherein the predicted control settings affect one or more of intensity, shape and position of the ion beam;
applying the predicted control settings to adjust the beam current density profile in the region of a workpiece.

10. The method of claim 9, further comprising a method to measure the horizontal beam angle (“HBA”) and or vertical beam angle (“VBA”) of the ion beam.

11. The method of claim 9, wherein generating a set of predicted control settings further comprises applying an artificial intelligence (AI) process including one or more of generative adversarial networks (GANS), autoencoder transformer, deep reinforcement learning, deep neural networks or curve force fitting.

12. The method of claim 9, further comprising collecting current beam density measurement valued from one or more side mounted measurement sensors, centrally located tuning beam current measurement sensor, and one or more independently monitored beam current measurement sensor slits positioned across from the implantation workpiece.

13. The method of claim 9, further comprising collecting beam current density measurement values from a power supply readback, from a power supply biasing the Beam Tunnel and from a sensor positioned to detect a current change due to ion beam position change.

14. The method of claim 13, wherein the power supply readback comprises a Terminal Return Current (TRC).

15. The method of claim 9, further comprising sampling the ion beam with a traveling beam current measurement device to obtain a direct measure of the beam current density distribution in the region of the workpiece.

16. A non-transitory, computer readable storage medium containing instructions stored thereon that, when executed, implement a method of implementing automatic beam current density distribution tuning for an ion implantation system on an implantation workpiece, the instructions comprising:
generating an ion beam;
displacing the ion beam in a direction orthogonal to the direction of motion of the implantation workpiece through a control signal;
obtaining an input signal from one or more stationary sensors configured to detect an ion beam current density value, wherein the input signal comprises an input waveform generated by synchronizing the beam current density signal from the one or more stationary sensors with the control signal;
generating a set of predicted control settings for beam tuning, wherein the predicted control settings affect one or more of intensity, shape and position of the ion beam;
applying the predicted control settings to adjust the beam current density profile in a region of the workpiece.

17. The medium of claim 16, the instructions further comprising measuring the one or more of horizontal or vertical beam angles associated with the ion beam and applying the measurements to generating the set of predicted control settings.

18. The medium of claim 16, wherein generating a set of predicted control settings further comprise applying an artificial intelligence (AI) process including one or more of generative adversarial networks (GANS), autoencoder transformer, deep reinforcement learning, deep neural networks or curve force fitting to thereby generate the predicted settings for the beam tuning controls.

19. The medium of claim 16, the instructions further comprising collecting signals from at least one of a side mounted beam current measurement device, a centrally located tuning beam current measurement device, and an independently monitored beam current measurement device slits positioned across the area of the workpiece.

20. The medium of claim 16, the instructions further comprising collecting signals from one or more of a power supply readback, a current readback from a power supply biasing a Beam Tunnel and any sensor sensitive to ion beam current change arising from the ion beam's position change.

21. The medium of claim 16, the instructions further comprising further modifying the predicted tuning control settings to adjust the beam current density distribution in the region of the workpiece.

22. The medium of claim 16, the instructions further comprising sampling the ion beam with a traveling beam current measurement device to directly measure the beam current density distribution in the region of the workpiece.
